(19) United States
(12) Patent Application Publication
(10) Pub. No.: US 2014/0196945 A1
(43) Pub. Date: Jul. 17, 2014

(54) TERMINAL BOX, SOLAR CELL MODULE WITH TERMINAL BOX, AND METHOD FOR MANUFACTURING SOLAR CELL MODULE WITH TERMINAL BOX

(71) Applicant: Shiro Kato, Osaka-shi (JP)

(72) Inventor: Shiro Kato, Osaka-shi (JP)

(73) Assignee: SHARP KABUSHIKI KAISHA, Osaka-shi, Osaka (JP)

(21) Appl. No.: 14/238,325

(22) PCT Filed: Jun. 26, 2012
(86) PCT No.: PCT/JP2012/066269

§ 371 Date: Feb. 11, 2014

(30) Foreign Application Priority Data
Aug. 25, 2011 (JP) 2011-183906

(51) Int. Cl. H05K 5/06; H01R 43/00; H05K 5/02; H01L 31/048

(52) U.S. Cl. CPC H05K 5/064; H01L 31/0485; H01R 43/005; H05K 5/0247; H05K 5/0213
USPC 174/522; 29/855

(57) ABSTRACT

A terminal box includes a terminal box main body (M), a terminal plate (3) to which a lead wire (2) introduced in the terminal box main body (M) is coupled, and a fixed portion (4) that secures at least the terminal plate (3) to the terminal box main body (M). The terminal box includes a filler (7) that seals a peripheral area of the terminal plate (3). The terminal plate (3) includes an opening portion (3b) that serves as a filler supply port and an air vent port.

### TECHNICAL FIELD

The present invention relates to a terminal box, a solar cell module with the terminal box, and a method for manufacturing the solar cell module with the terminal box.

### BACKGROUND ART

Recently, use of a solar cell system, which generates electricity using solar light, has been popular. The solar cell system has been widely spread in ordinary homes. The solar cell system converts a direct current from a solar cell module installed on a roof of a building via an inverter, for example, and supplies the converted alternate current to each electrical product.

The solar cell module is usually laid on a predetermined mounting so as to be a flat surface. Each module is coupled in series or in parallel to one another via a terminal box.

Patent Literature 1 discloses the following terminal box. A lead wire extracted from a solar cell module is introduced into a terminal box. A terminal portion, which is a terminal plate included in the terminal box, is coupled to the lead wire with solder.

Incidentally, since the terminal box is installed outdoor together with the solar cell module and therefore is exposed to rain water, dust, or similar object, the rain water, dust, or similar object may enter the terminal box. In the terminal box described in Patent Literature 1, components such as the terminal plate and the lead wire are all exposed in the terminal box. Accordingly, entrance of rain water and dust or similar object in the terminal box may result in a short circuit and deterioration of parts, for example.

Meanwhile, Patent Literature 2 discloses a terminal box gaplessly filled up with a silicon resin agent in the terminal box. This type of terminal box coats components such as a terminal plate and a lead wire with the filling agent. The problem apprehended in the above-described terminal box of Patent Literature 1 does not occur.

Accordingly, the following is considered in the terminal box of Patent Literature 1 as well. As disclosed in Patent Literature 2, the inside of the terminal box is filled up with a filler to protect the components such as the terminal plate and the lead wire.

### CITATION LIST

### Patent Literature

PATENT LITERATURE 1: “Japanese Unexamined Patent Application Publication No. 2005-353734”

PATENT LITERATURE 2: “Japanese Unexamined Patent Application Publication No. 2004-134717”

### SUMMARY OF INVENTION

### Technical Problem

However, if the inside of the terminal box of Patent Literature 1 is filled up with a filler as disclosed in Patent Literature 2, the following inconvenience occurs. The following describes this respect with reference to FIG. 8 to FIG. 10.

FIG. 8 is a plan view of a terminal box. FIG. 9 is a partial cross-sectional view taken along the line IX-IX of FIG. 8. FIG. 10 is a cross-sectional view viewed from the arrow A in FIG. 9.

A terminal box 100 is mounted on a rear surface of a solar cell module M1 (see FIG. 9). The terminal box 100 includes a terminal box main body 101, a terminal plate 103, a fixed portion 104, and a partition plate 105 as illustrated in FIG. 8. The terminal box main body 101 has an open top surface. The terminal plate 103 couples a lead wire 102 extracted from the solar cell module M1. The fixed portion 104 secures the terminal plate 103 at a position away from the bottom surface of the terminal box main body 101 with a posture where a rear surface of the terminal plate 103 faces the bottom surface of the terminal box main body 101. The partition plate 105 is disposed upright on the bottom surface of the terminal box main body 101 and surrounds the terminal plate 103. In the terminal box illustrated in FIG. 8, a plurality of terminal plates are disposed sandwiching the partition plate 105 in the terminal box main body 101 according to the number of a plurality of positive or negative lead wires 102 extracted from the installed solar cell module. In this example, an exemplary case where the number of the lead wires 102 is two is illustrated. The partition plate 105 is disposed with the aim of preventing incorrect contact between the neighboring terminal plates 103 and preventing causing a short circuit.

The terminal box main body 101 includes a lead wire introduction inlet 101a. The lead wire introduction inlet 101a introduces the lead wire 102 extracted from the solar cell module M1 to the inside of the terminal box main body. The terminal plate 103 is provided with a lead wire insertion hole 103a (see FIG. 9). The lead wire 102 extracted from the solar cell module M1 is inserted through the lead wire insertion hole 103a.

The terminal box 100 thus formed is mounted on the rear surface of the solar cell module M1 with the lead wire 102 (specifically, a rear-surface protective sheet (back film) BS1). The lead wire 102 is passed through the lead wire introduction inlet 101a in the terminal box main body 101 and introduced in the terminal box main body 101. Furthermore, the distal end portion of the lead wire 102 introduced in the terminal box main body 101 is inserted through the lead wire insertion hole 103a of the terminal plate 103. The distal end portion is coupled to the terminal plate 103 with a solder 108 near the lead wire insertion hole 103a.

In this state, a filler 107 is supplied from upward of the terminal plate 103. Afterwards, the upper portion of the terminal box main body 101 is sealed with an upper lid 109. However, in supplying the filler 107 from upward of the terminal plate 103, the terminal plate 103 interferes a flow of the filler 107. The filler 107 does not reach a space 106, which is provided between the rear surface of the terminal plate 103 and the bottom surface of the terminal box main body 101, across the entire region. Accordingly, a hollow V is generated at the space 106 due to insufficient filling (see FIG. 9 and FIG. 10). That is, the filler 107 circumvents the terminal plate 103 and enters from narrow spaces such as both end portion sides of the terminal plate 103 and gaps between respective internal side surfaces of the partition plates 105 and 105 and both side edges of the terminal plate 103 so as to be supplied to inside of the space 106. Therefore, the filler 107 does not sufficiently reach the space 106, the hollow V is generated at the space 106. This causes an inconvenience that the inside of the terminal box main body 101 cannot be sufficiently sealed with the filler 107, for example. In particular, use of the filler 107 with comparatively high viscosity or the filler 107 with quick hardening speed tends to remarkably generate the hollow V due to insufficient filling.

In view of the foregoing, the present invention has been achieved. It is an object of the present invention to provide a terminal box that reduces generation of a hollow at a space between a rear surface of a terminal plate and a bottom surface of a terminal box main body due to insufficient filling by the filler, a solar cell module with the terminal box, and a method for manufacturing the solar cell module with the terminal box.

### Solutions to the Problems

In order to attain the above object, the present invention is configured as follows.

A terminal box according to the present invention includes a terminal box main body, a terminal plate to which a lead wire introduced in the terminal box main body is coupled, and a fixed portion that secures the terminal plate to the terminal box main body. The terminal box includes a filler that seals at least a peripheral area of the terminal plate. The terminal plate includes an opening portion that serves as a filler supply port and an air vent port.

With this configuration, when the peripheral area of the terminal plate is sealed with the filler, the filler is smoothly supplied from the opening portion disposed at the terminal plate to the rear surface side of the terminal plate as well. This also ensures removing air bubble generated in the filling, thus reducing generation of a hollow around the terminal plate.

The above-described terminal box is configured as follows. A partition plate is disposed upright on the terminal box main body. The partition plate is close to the terminal plate. A space in the terminal box main body including the terminal plate surrounded by the partition plates is sealed with a filler. In this case, the space partitioned with the partition plates is formed around the terminal plate in the terminal box main body. Even in this case, when the peripheral area of the terminal plate is sealed with the filler, the filler is smoothly supplied from the opening portion disposed at the terminal plate to the rear surface side of the terminal plate as well. This also ensures removing air bubble generated in the filling, thus reducing generation of a hollow in the space.

The the opening portion may be a hole.

In the above-described terminal box, the hole may be formed at a center portion of the terminal plate in a direction perpendicular to a direction that the lead wire is coupled. In this case, the filler can be evenly supplied to the rear surface side of the terminal plate, further reducing generation of a hollow around the terminal plate.

The opening portion may be a cutout portion formed at the terminal plate. Here, the cutout portion is not limited to one but may be plural. The plurality of cutout portions ensure evenly supplying the filler to the rear surface side of the terminal plate, further reducing generation of a hollow around the terminal plate.

In the above-described terminal box, when the fixed portions are disposed at least two positions, the hole serving as an opening portion is preferred to be disposed between the fixed portions.

If, for example, the fixed portions are aligned with distance at two positions, a space between the fixed portions is narrower compared with other parts and therefore a flow of the filler here tends to be stuck. This makes filling between the fixed portions difficult. However, when the opening portion is disposed between the fixed portions, generation of a hollow between the fixed portions is reduced, thus ensuring filling the filler.

In the above-described terminal box, when the fixed portions are disposed at least two positions and the opening portion is formed as a cutout portion, the cutout portion is preferred to be formed from a side end portion of the terminal plate to between the fixed portions.

If, for example, the fixed portions are aligned with distance at two positions, a space between the fixed portions is narrower compared with other parts and therefore a flow of the filler here tends to be stuck. This makes filling between the fixed portions difficult. However, when the cutout portion, which is the opening portion, is formed from the side end portion of the terminal plate to between the fixed portions, generation of a hollow between the fixed portions is reduced, thus ensuring filling the filler.

The solar cell module according to the present invention includes the above-described terminal box.

A method for manufacturing the above-described solar cell module is as follows. The terminal box includes a terminal box main body, a terminal plate to which a lead wire introduced in the terminal box main body is coupled, and a fixed portion that secures the terminal plate to the terminal box main body. The terminal box includes a filler that seals at least a peripheral area of the terminal plate. The method includes: mounting to the solar cell module the terminal box main body with the terminal plate having an opening portion that serves as an opening portion; inserting the lead wire extracted from the solar cell module and introduced to the terminal box main body into an insertion hole of the terminal plate; coupling the lead wire and the terminal plate with a solder; and filling a filler to the terminal box main body and a filler from an opening portion that serves as an opening portion of the terminal plate to a rear surface side of the terminal plate to seal.

The above-described method allows manufacturing a solar cell module with a terminal box that reduces generation of a hollow around a terminal plate due to insufficient filling by a filler.

### Advantageous Effects of Invention

According to the present invention, generation of a hollow at a space between a rear surface of the terminal plate and a bottom surface of the terminal box due to insufficient filling by the filler can be reduced.

### BRIEF DESCRIPTION OF DRAWINGS

FIG. 1 is a plan view illustrating one embodiment of a terminal box according to the present invention.

FIG. 2 is a cross-sectional view taken along the line II-II of FIG. 1.

FIG. 3 is a cross-sectional view of the terminal box illustrating a state of completion of filling of a filler.

FIG. 4 is a plan view illustrating another embodiment of the terminal box according to the present invention.

FIG. 5 is a cross-sectional view taken along the line V-V of FIG. 4.

FIG. 6 is a plan view illustrating yet another embodiment of the terminal box according to the present invention.

FIG. 7 is a plan view illustrating yet another embodiment of the terminal box according to the present invention.

FIG. 8 is a plan view of a conventional terminal box.

FIG. 9 is a cross-sectional view taken along the line IX-IX of FIG. 8.

FIG. 10 a cross-sectional view of the terminal box viewed from the side indicated by the arrow A illustrated in FIG. 9.

### DESCRIPTION OF EMBODIMENTS

Hereinafter, embodiments according to the present invention will be described with reference to the accompanying drawings.

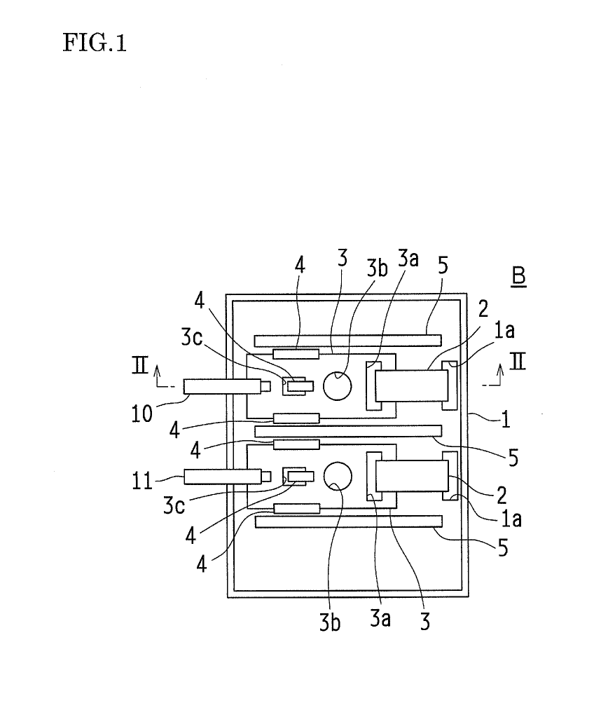

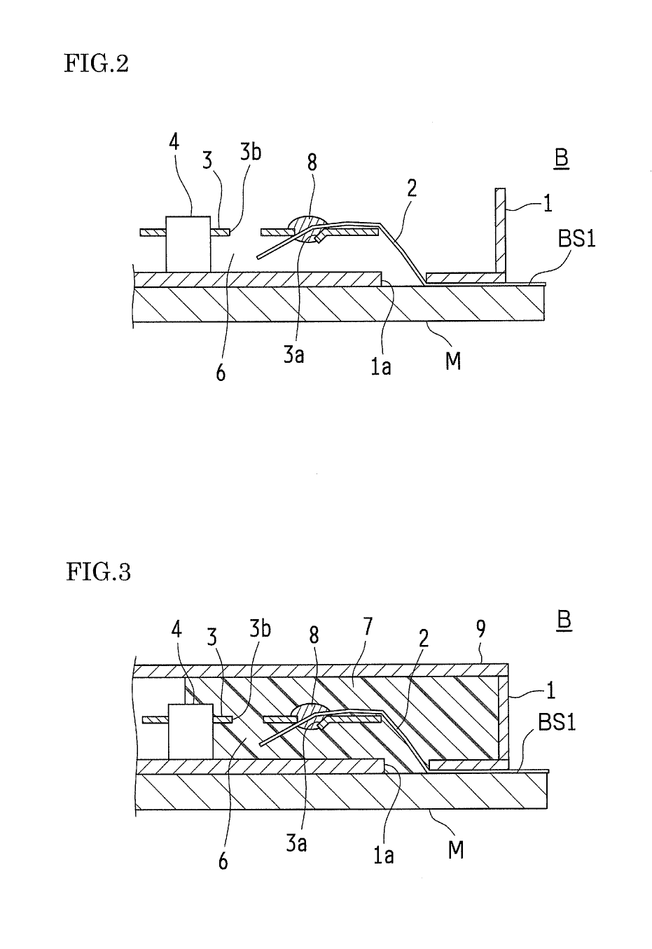

FIG. 1 is a plan view illustrating one embodiment of a terminal box according to the present invention. FIG. 2 is a cross-sectional view taken along the line II-II of FIG. 1. FIG. 3 is a cross-sectional view of the terminal box illustrating a state of completion of filling of a filler.

A terminal box B according to the embodiment is mounted on a rear surface (specifically, a rear-surface protective sheet (back film) BS) of a solar cell module M (see FIG. 2). As illustrated in FIG. 1, the terminal box B includes a terminal box main body 1, two terminal plates 3, and fixed portions 4. The terminal box main body 1 has an open top surface. The terminal plates 3 are coupled each of positive or negative lead wire 2 extracted from the solar cell module M, respectively. The fixed portions 4 secure these terminal plates 3. Here, the fixed portions 4 have a structure that secures the terminal plates 3 at three positions: both side edge portions of the terminal plate 3 and an opening 3c disposed at the terminal plate 3 so as to position the terminal plate 3 away from the bottom surface of the terminal box main body 1 with a posture where each rear surface of the terminal plate 3 faces the bottom surface of the terminal box main body 1. While a partition plate 5 is disposed with the aim of preventing incorrect contact between the neighboring terminal plates 3 and a short circuit, the partition plate 5 may not be disposed.

The terminal box main body 1 includes a lead wire introduction inlet 1a (see FIG. 2). The lead wire introduction inlet 1a introduces each lead wire 2 extracted from the solar cell module M to the inside of the terminal box main body 1, respectively. The lead wire 2 introduced in the terminal box main body 1 through the lead wire introduction inlet 1a is inserted through a lead wire insertion hole 3a of the terminal plate 3 from upward of the terminal plate 3. The lead wire 2 is coupled to the terminal plate 3 with a solder 8 near the lead wire insertion hole 3a. Furthermore, respective positive or negative power supply wires 10 and 11 are coupled to the respective terminal plates 3.

The terminal plate 3 includes the lead wire insertion hole 3a, the opening portion 3b, and the opening 3c. The lead wire 2 extracted from the solar cell module M is inserted through the lead wire insertion hole 3a. The opening portion 3b supplies a space 6 (see FIG. 2) partitioned with the rear surface of the terminal plate 3 and the partition plate 5 with a filler 7 or removes an air bubble generated in supply of the filler. The opening 3c is engaged with and secured to the fixed portion 4. While in this embodiment the opening portion 3b has a circular hole, the opening portion 3b may have another shape, such as an oval, a rectangular, a triangle, a polygon equal to or more than a pentagon as long as the opening portion 3b communicates with the space 6 and enables the smoothly supply of the filler 7. The number of the opening portions 3b is not limited to one per terminal plate as the above-described embodiment, but a plurality of the opening portions 3b may be formed. Furthermore, the terminal plate 3 is not limited to two, but may be equal to or more than three.

To fill the terminal box B formed as described above with the filler 7, the filler 7 is supplied from upward of the terminal plate 3. Then, the filler 7 flows into the space 6 through the opening portion 3b of the terminal plate 3. An air bubble generated in supply of the filler exits from the opening portion 3b and another gap, finally gaplessly filling up the space 6 with the filler 7. Here, as the material of the filler 7, since near the lead wire insertion hole 3a and near the power supply wires 10 and 11, for example, become a high temperature due to a current generated by the solar cell module M, resin excellent in flame resistant and incombustibility is preferred. Silicon resin is used, for example. As the filler, an insulating resin is used to prevent conduction between the terminal and the wiring.

Similarly to the opening portion 3b, the lead wire insertion hole 3a is also an opening portion disposed at the terminal plate 3. However, the lead wire insertion hole 3a is blocked with the solder 8 in coupling the lead wire 2. Accordingly, different from the opening portion 3b, it is difficult to supply the filler 7 from the lead wire insertion hole 3a after solder coupling.

After filling the filler 7 as described above, an upper lid 9 is attached to the terminal box main body 1, completing sealing of the terminal box B.

As described above, the terminal box B where generation of a hollow due to insufficient filling by the filler is reduced in the space 6 can be provided.

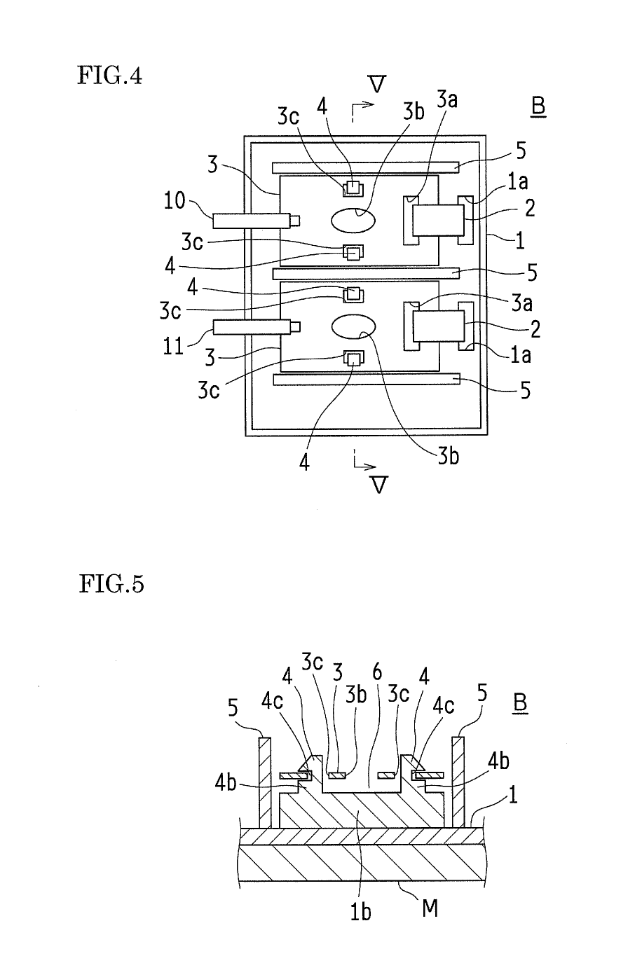

Next, another embodiment of the terminal box according to the present invention will be described by referring to FIG. 4 and FIG. 5.

FIG. 4 is a plan view illustrating the terminal box. FIG. 5 is a cross-sectional view taken along the line V-V of FIG. 4.

This embodiment is different from the embodiment illustrated in FIG. 1 to FIG. 3 only in specifications of a configuration of the fixed portion and positions of the opening portion as a filler supply port and an air vent port. Accordingly, only the differences will be described below. Like reference numerals designate corresponding or identical elements throughout the above-described embodiment and the following embodiment, and therefore such elements will not be further elaborated here.

The terminal box main body 1 includes a fixed portion pedestal 1b (see FIG. 5) at the inner bottom surface. The fixed portions 4 are disposed on the fixed portion pedestal 1b. The fixed portions 4 include a pair of legs 4b and grooves 4c. The pair of legs 4b are disposed to protrude from the fixed portion pedestal 1b. The groove 4c. which engages a side edge portion of the terminal plate 3, is formed at the outer side surface opposite to the surface facing the opposed leg 4b. Meanwhile, the terminal plate 3 includes the opening 3c at a position corresponding to the leg 4b of the fixed portion 4. The opening 3c engages the groove 4c. Accordingly, in the terminal plate 3, the opening 3c of the terminal plate 3 is engaged with and secured to the groove 4c of the leg 4b at a position away from the bottom surface of the terminal box main body 1 with a posture facing the bottom surface of the terminal box main body 1. Here, the number of the legs 4b of the fixed portions 4 and the number of the openings 3c of the terminal plates 3 are not limited to two but may be equal to or more than three. The fixed portion 4 is not limited to be disposed to protrude from the fixed portion pedestal 1b. The fixed portion 4 may be disposed to protrude directly from the bottom surface of the terminal box main body 1 without through the fixed portion pedestal 1b.

The opening portion 3b of this embodiment is disposed between the opposed legs 4b and 4b. That is, it is preferred that the opening portion 3b be positioned into which the filler 7 is difficult to flow with the fixed portions 4. Like an example of illustrated drawing, in the case where the two legs 4b and 4b are spaced so as to face to one another, the filler 7 is particularly difficult to flow into between the legs 4b and 4b. Accordingly, positioning the opening portion 3b between the legs 4b and 4b, which secure the terminal plates 3, is preferred. If the number of the legs 4b is equal to or more than three per terminal plate, the opening portion 3b is positioned between each leg 4b. Consequently, the opening portion 3b may be plural.

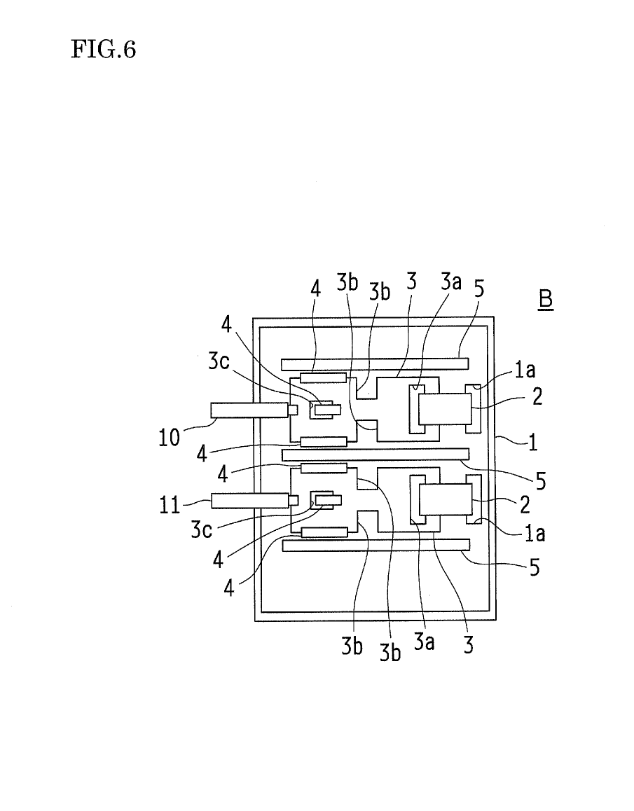

Next, yet another embodiment of the terminal box according to the present invention will be described by referring to the plan view of the terminal box illustrated in FIG. 6.

This embodiment is different from the embodiment illustrated in FIG. 1 to FIG. 3 only in a form of the opening portion as a filler supply port and an air vent port. Accordingly, only the differences will be described below. Like reference numerals designate corresponding or identical elements throughout the above-described embodiment and the following embodiment, and therefore such elements will not be further elaborated here.

In this embodiment, cutout portions are formed as the opening portion 3b at both side edge portions of the terminal plate 3. This cutout portion (the opening portion) 3b is square notched. However, the cutout portion may have another shape, such as a polygon and an arc, as long as the filler 7 can be smoothly supplied to the space 6. The cutout portion 3b may be disposed at equal to or more than three positions per terminal plate.

Assume that the cutout portion 3b is disposed at the terminal plate 3. In the case where the filler 7 is supplied from upward of the terminal plate 3, the filler 7 flows into the space 6 through the cutout portion (the opening portion) 3b of the terminal plate 3, thus the space 6 is filled up with the filler.

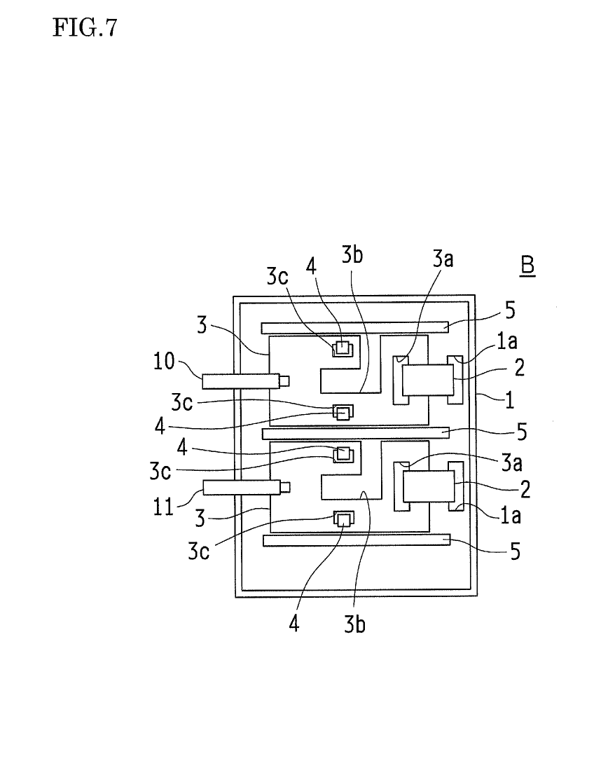

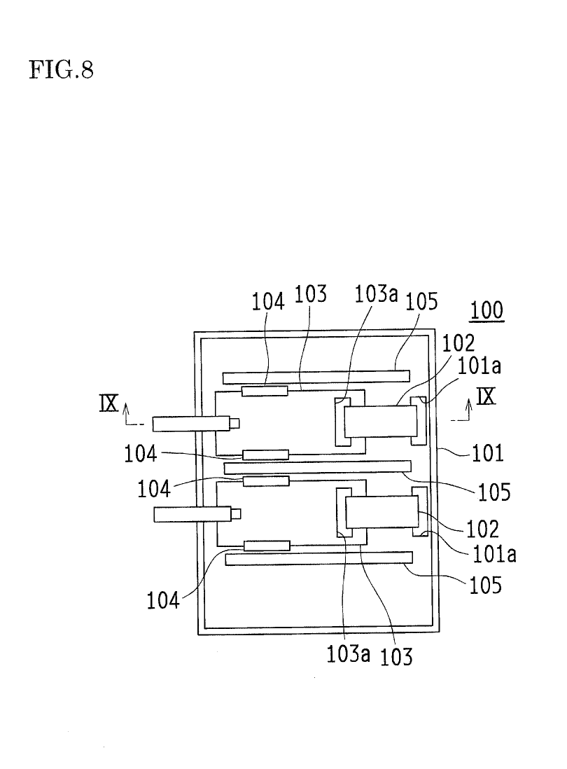

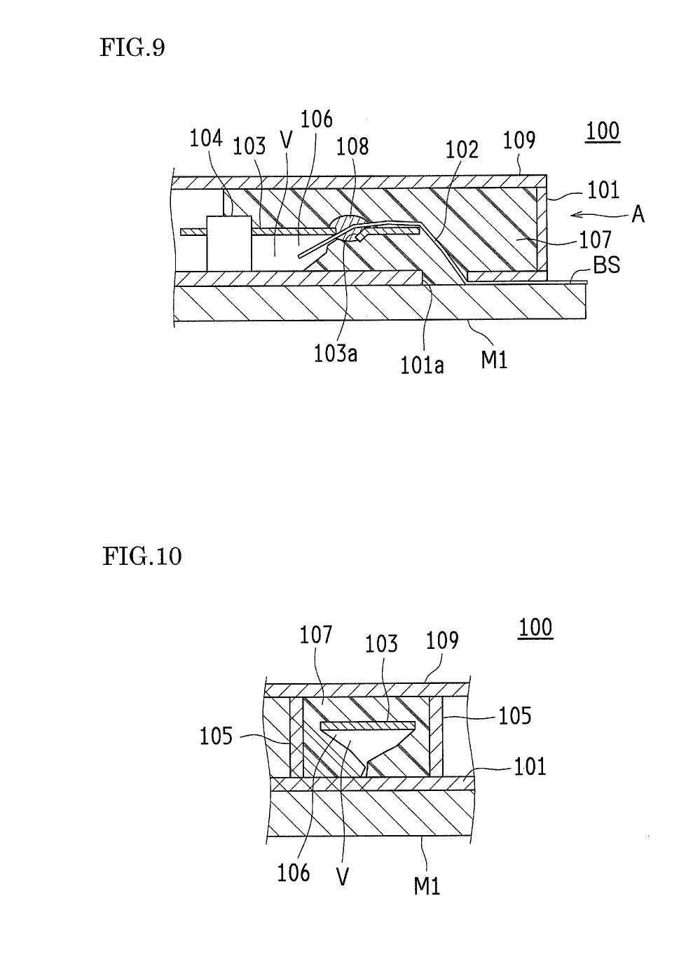

Next, yet another embodiment of the terminal box according to the present invention will be described by referring to the plan view of the terminal box illustrated in FIG. 7.

This embodiment is different from the embodiment illustrated in FIG. 1 to FIG. 3 only in a form of the opening portion as a filler supply port and an air vent port. Accordingly, only the differences will be described below. Like reference numerals designate corresponding or identical elements throughout the above-described embodiment and the following embodiment, and therefore such elements will not be further elaborated here.

In this embodiment, the cutout portion (the opening portion) 3b is a cutout portion formed to an L shape. The L-shaped cutout portion is constituted of a square-shaped opening, which is positioned at the center of the terminal plate 3 between the fixed portions 4, and an opening, which couples one end of the square-shaped opening to one side edge portion of the terminal plate 3. Assume that the cutout portion (the opening portion) 3b is disposed at the terminal plate 3. In the case where the filler 7 is supplied from upward of the terminal plate 3, the filler 7 flows into the space 6 through the L-shaped cutout portion (the opening portion) 3b of the terminal plate 3, thus the space 6 is filled up with the filler.

Subsequently, a method for manufacturing the solar cell module with the terminal box of the present invention will be described by referring to FIG. 1 to FIG. 3.

A first process is as follows. The lead wire 2 extracted from the solar cell module M is introduced from the lead wire introduction inlet 1a at the bottom surface of the terminal box main body 1 according to the embodiment. Meanwhile, the terminal box main body 1 is mounted on the solar cell module M. At the moment, the terminal box main body 1 is bonded to the solar cell module M with an adhesive (not illustrated), for example, and secured to one another.

As a second process, the lead wire 2, which is introduced in the terminal box main body 1, is inserted through the lead wire insertion hole 3a of the terminal plate 3 from the top surface of the terminal plate 3.

As a third process, the terminal plate 3 and the lead wire 2 are coupled with the solder 8 from upward near the lead wire insertion hole 3a.

As a fourth process, the filler 7 is supplied in the terminal box main body 1 from upward of the terminal plate 3. Then, the filler 7 flows into the space 6 through the opening portion 3b of the terminal plate 3, simultaneously, air exits from the space 6. Thus, the space 6 is gaplessly filled up with the filler 7.

As a fifth process, the upper lid 9 for the terminal box main body 1 is installed, thus completing installation of the terminal box 1 to the solar cell module M.

The method for manufacturing the solar cell module including the mounting process of the terminal box allows manufacturing the solar cell module M with the terminal box B where generation of a hollow due to insufficient filling by the filler is reduced in the space 6.

### DESCRIPTION OF REFERENCE SIGNS

1 terminal box main body
1a lead wire introduction inlet
1b fixed portion pedestal
2 lead wire
3 terminal plate
3a lead wire insertion hole
3b opening portion
3c opening
4 fixed portion
4b leg
4c groove
5 partition plate
6 space
7 filler
8 solder
9 upper lid
M solar cell module
B terminal box

1. A terminal box, comprising:
a terminal box main body;
a terminal plate to which a lead wire introduced in the terminal box main body is coupled; and
a fixed portion that secures the terminal plate to the terminal box main body, wherein
the terminal box includes a filler that seals a peripheral area of the terminal plate, and
the terminal plate includes an opening portion that serves as a filler supply port and an air vent port.

2. The terminal box according to claim 1, further comprising
a partition plate disposed upright on the terminal box main body, the partition plate being close to the terminal plate, wherein
a space in the terminal box main body including the terminal plate surrounded by the partition plates is sealed with a filler.

3. The terminal box according to claim 1, wherein
the opening portion is a hole.

4. The terminal box according to claim 3, wherein
the hole is formed at a center portion of the terminal plate in a direction perpendicular to a direction that the lead wire is coupled.

5. The terminal box according to claim 3, wherein
the fixed portions are disposed at least two positions,
the terminal plate is secured to a plurality of the fixed portions, and the hole is disposed between the fixed portions.

6. The terminal box according to claim 1, wherein the opening portion is a cutout portion formed at a side end portion of the terminal plate.

7. The terminal box according to claim 6, wherein
the fixed portions are disposed at least two positions,
the terminal plate is secured to a plurality of the fixed portions, and
the cutout portion is formed from a side end portion of the terminal plate to between the fixed portions.

8. A solar cell module, comprising
the terminal box according to claim 1.

9. A method for manufacturing a solar cell module with a terminal box, the terminal box including a terminal box main body, a terminal plate to which a lead wire introduced in the terminal box main body is coupled, and a fixed portion that secures at least the terminal plate to the terminal box main body, the terminal box including a filler that seals at least a peripheral area of the terminal plate, the terminal plate including an opening portion that serves as a filler supply port and an air vent port, the method comprising:
mounting the terminal box main body to the solar cell module;
inserting the lead wire extracted from the solar cell module and introduced to the terminal box main body into an insertion hole of the terminal plate;
coupling the lead wire and the terminal plate with a solder; and
filling a filler to the terminal box main body and a filler from the opening portion to a rear surface side of the terminal plate to seal.
